(19) United States
(12) Patent Application Publication
(10) Pub. No.: US 2025/0279308 A1
(43) Pub. Date: Sep. 4, 2025

(54) MEMBER FOR SEMICONDUCTOR MANUFACTURING EQUIPMENT

(71) Applicant: NGK INSULATORS, LTD., Nagoya-Shi (JP)

(72) Inventors: Shingo AMANO, Chita-Gun (JP); Naoki TSUZUKI, Toyoake-Shi (JP); Yohei KAJIURA, Nagoya-Shi (JP)

(73) Assignee: NGK INSULATORS, LTD., Nagoya-Shi (JP)

(21) Appl. No.: 18/815,928

(22) Filed: Aug. 27, 2024

Related U.S. Application Data
(63) Continuation of application No. PCT/JP2024/007630, filed on Feb. 29, 2024.

(51) Int. Cl. H01L 21/683; H01L 21/67

(52) U.S. Cl. CPC H01L 21/6833; H01L 21/67103

(57) ABSTRACT

A member for a semiconductor manufacturing equipment includes a ceramic substrate including: a terminal dense portion, a plurality of heater electrodes which are zoned, and a plurality of jumper electrode layers; wherein each of the jumper electrode layers is composed of a plurality of planar jumper electrodes that are electrically isolated by an insulator, and wherein in at least one of the terminal dense portion, each of 70% or more of all the terminals arranged in the terminal dense portion is electrically connected to a predetermined planar jumper electrode through a first via extending in the vertical direction, on a condition that it is not electrically connected to a planar jumper electrode located in a layer above any other planar jumper electrode to which other terminals that have a longer distance from an outer periphery of the terminal dense portion than itself are electrically connected.

### CROSS REFERENCE TO RELATED APPLICATIONS

The present invention claims the benefit of priority to International Patent Application PCT/JP2024/007630 filed on Feb. 29, 2024 with the Japanese Patent Office, the entire contents of which are incorporated herein by reference in its entirety.

### FIELD OF THE INVENTION

The present invention relates to a member for a semiconductor manufacturing equipment.

### BACKGROUND OF THE INVENTION

Conventionally, members for semiconductor manufacturing equipment used for holding, temperature control, transporting, or the like of wafers have been known. These types of members for semiconductor manufacturing equipment are also called a wafer placement table, an electrostatic chuck, a susceptor, or the like. Generally, they have the function of applying electrical power for electrostatic adsorption to an internal electrode and adsorbing a wafer using electrostatic force.

There are many different types of processing for wafers, such as etching and CVD, and the optimum wafer temperature distribution differs depending on the type of processing. For this reason, a member for a semiconductor manufacturing equipment are required to have the ability to control the temperature distribution of the wafer. In order to meet such demands, a member for a semiconductor manufacturing equipment with a multi-zone heater that includes a ceramic substrate incorporating a plurality of heater electrodes is known.

Japanese Patent Application Publication No. 2021-015933 discloses that a heater electrode layer having a plurality of heater electrodes formed of a conductive material, a driver electrode layer having a plurality of driver electrodes for supplying power to the heater electrode layer, and various vias are disposed inside a ceramic plate-shaped member. The literature also discloses that a plurality of power supply pads are arranged in a direction substantially perpendicular to the vertical direction in a positioning recess on the lower surface of the plate-like member, and each power supply pad is electrically connected to a driver electrode of the driver electrode layer through a via. The drawings in this literature show a number of driver electrodes arranged at different heights.

### PRIOR ART

### Patent Literature

[Patent Literature 1] Japanese Patent Application Publication No. 2021-015933

### SUMMARY OF THE INVENTION

In such a member for a semiconductor manufacturing equipment with multi-zone heaters, there is a demand for improved performance in controlling the temperature distribution of the wafer in order to accommodate more precise wafer processing. To improve the ability to control the temperature distribution on the wafer, it is necessary to increase the number of zones by increasing the number of heater electrodes. However, as the number of heater electrodes increases, the number of driver electrodes (hereinafter referred to as “jumper electrodes” in this specification) for supplying power to the heater electrodes also increases. As the number of jumper electrodes increases, it becomes necessary to make the jumper electrodes multi-layered, and the number of layers also increases, which increases the number of manufacturing steps for the ceramic substrate, resulting in a problem that the manufacturing costs of a member for a semiconductor manufacturing equipment tend to rise.

In view of the above circumstances, in one embodiment of the present invention, an object is to reduce the number of jumper electrode layers in a member for a semiconductor manufacturing equipment having a plurality of zoned heater electrodes.

As a result of intensive research conducted by the present inventors to solve the above problems, the present invention, which is illustrated as below, has been created.

### Aspect 1

A member for a semiconductor manufacturing equipment comprising a ceramic substrate, the ceramic substrate comprising:
an upper surface on which a wafer is to be placed,
a terminal dense portion in which 10 or more terminals are arranged within a single section,
a plurality of heater electrodes which are zoned, and
a plurality of jumper electrode layers that electrically connect the plurality of heater electrodes to each terminal of the terminal dense portion and are stacked in a vertical direction via an insulator;
wherein each of the jumper electrode layers is composed of a plurality of planar jumper electrodes that are electrically isolated by an insulator,
wherein in at least one of the terminal dense portion, each of 70% or more of all the terminals arranged in the terminal dense portion is electrically connected to a predetermined planar jumper electrode through a first via extending in the vertical direction, on a condition that it is not electrically connected to a planar jumper electrode located in a layer above any other planar jumper electrode to which other terminals that have a longer distance from an outer periphery of the terminal dense portion than itself are electrically connected, and
wherein each of the plurality of planar jumper electrodes is electrically connected to a first connection portion of a predetermined heater electrode selected from the plurality of heater electrodes through a second via extending in the vertical direction.

### Aspect 2

A member for a semiconductor manufacturing equipment according to aspect 1, wherein in at least one of the terminal dense portion, at least one terminal T₁ is electrically connected to a planar jumper electrode located in a layer above a planar jumper electrode to which at least one other terminal T₂, which has a longer distance from the outer periphery of the terminal dense portion than the at least one terminal T₁, is electrically connected; and wherein assuming a distance between the at least one terminal T₁ and the outer periphery is M₁ (mm), and a distance between the at least one other terminal T₂ and the outer periphery is M₂ (mm), a formula 1: M₁<M₂≤M₁+2 is satisfied for all of the at least one terminal T₁.

### Aspect 3

A member for a semiconductor manufacturing equipment according to aspect 1, wherein in at least one of the terminal dense portion, each of all the terminals arranged in the terminal dense portion is electrically connected to the predetermined planar jumper electrode through the first via extending in the vertical direction, on the condition that it is not electrically connected to the planar jumper electrode located in the layer above any other planar jumper electrode to which other terminals that have a longer distance from the outer periphery of the terminal dense portion than itself are electrically connected.

### Aspect 4

A member for a semiconductor manufacturing equipment according to any one of aspects 1 to 3, wherein at least one jumper electrode layer among the plurality of jumper electrode layers electrically connected to the 10 or more terminals constituting the terminal dense portion in each single section is composed of 8 to 12 planar jumper electrodes.

### Aspect 5

A member for a semiconductor manufacturing equipment according to any one of aspects 1 to 4, wherein assuming a total number of the plurality of jumper electrode layers electrically connected to the 10 or more terminals constituting the terminal dense portion in each single section is A, a number of planar jumper electrodes constituting a N^{th} jumper electrode layer (N is a natural number from 1 to A) from a lowermost layer is equal to or less than a number of planar jumper electrodes constituting the (N−1)^{th} jumper electrode layer from the lowermost layer, and a number of the planar jumper electrodes constituting the uppermost jumper electrode layer is less than a number of the planar jumper electrodes constituting the lowermost jumper electrode layer.

### Aspect 6

A member for a semiconductor manufacturing equipment according to any one of aspects 1 to 5, wherein each of the plurality of planar jumper electrodes constituting at least one jumper electrode layer among the plurality of jumper electrode layers electrically connected to the 10 or more terminals constituting the terminal dense portion in each single section has a planar shape having two adjacent line segments at the same angle with a position of the first via as a vertex.

### Aspect 7

A member for a semiconductor manufacturing equipment according to any one of aspects 1 to 6, wherein each of the plurality of the heater electrodes has a second connection portion, and the second connection portion is connected to a common terminal for grounding via a common jumper.

### Aspect 8

A member for a semiconductor manufacturing equipment according to aspect 7, wherein the common jumper is electrically connected to the common terminal through a third via extending in the vertical direction, and a diameter of the third via is larger than a diameter of the first via.

### Aspect 9

A member for a semiconductor manufacturing equipment according to any one of aspects 1 to 8, wherein in each of the plurality of jumper electrode layers connected to the 10 or more terminals constituting the terminal dense portion in each single section, adjacent planar jumper electrodes are electrically isolated from each other by a linear insulator, and the linear insulator does not linearly overlap any other linear insulator in a different jumper electrode layer in the vertical direction.

### Aspect 10

A member for a semiconductor manufacturing equipment according to any one of aspects 1 to 9, wherein for any of the plurality of planar jumper electrodes constituting at least one jumper electrode layer among the plurality of jumper electrode layers connected to the 10 or more terminals constituting the terminal dense portion in each single section, a distance between adjacent planar jumper electrodes in the same layer is 0.3 mm or more.

According to the member for a semiconductor manufacturing equipment in one embodiment of the present invention, it is possible to reduce the number of layers of the jumper electrodes when the jumper electrodes are multi-layered by increasing the number of heater electrodes. This makes it possible to manufacture at low cost a member for a semiconductor manufacturing equipment with multi-zone heaters to improve wafer temperature distribution control performance.

### BRIEF DESCRIPTION OF THE DRAWINGS

FIG. 1 is a schematic vertical cross-sectional view (cross-sectional view taken along a plane including the central axis of the member for a semiconductor manufacturing equipment) of a member for a semiconductor manufacturing equipment according to one embodiment of the present invention.

FIG. 2 is a schematic partial enlarged view of the area enclosed by a frame in FIG. 1.

FIG. 3-1 is an arrangement example 1 of a terminal dense portion in a single section as observed from the bottom surface side of a ceramic substrate in a member for a semiconductor manufacturing equipment according to an embodiment of the present invention.

FIG. 3-2 is a diagram illustrating an example of jumper electrode layers to which each terminal in the terminal dense portion according to arrangement example 1 is connected, from the lowermost layer (the 1^{st} layer) to the uppermost layer (the 5^{th} layer).

FIG. 4-1 is a diagram showing an arrangement example 2 of a terminal dense portion in a single section as observed from the bottom surface side of a ceramic substrate in a member for a semiconductor manufacturing equipment according to an embodiment of the present invention.

FIG. 4-2 is a diagram illustrating an example of jumper electrode layers to which each terminal in the terminal dense portion according to arrangement example 2 is connected, from the lowermost layer (the 1^{st} layer) to the uppermost layer (the 5^{th} layer).

FIG. 5 shows schematic examples of the shapes of a plurality of planar jumper electrodes constituting each of the jumper electrode layers from the 1^{st} to the 5^{th} layers and an example of the shape of a common jumper, when the upper surface, which is the wafer placement surface of the ceramic substrate, is circular, the number of terminal dense portions is three, and the number of jumper electrode layers is five.

FIG. 6 is a schematic plan view of each of the 1^{st} to the 3^{rd} jumper electrode layers.

FIG. 7 is a schematic view of the five jumper electrode layers illustrated in FIG. 5 as viewed virtually from above.

### DETAILED DESCRIPTION OF THE INVENTION

Hereinafter, embodiments of the present invention will now be described in detail with reference to the drawings. It should be understood that the present invention is not intended to be limited to the following embodiments, and any change, improvement or the like of the design may be appropriately added based on ordinary knowledge of those skilled in the art without departing from the spirit of the present invention. In addition, as used herein, “upper” and “lower” are used to conveniently express the relative positional relationship when a member for a semiconductor manufacturing equipment is placed on a horizontal surface with the upper surface for placing a wafer of the ceramic substrate facing up, and they do not represent any absolute positional relationships. Therefore, depending on the orientation of the member for a semiconductor manufacturing equipment, “upper” and “lower” may become “lower” and “upper”, or “left” and “right”, or “front” and “rear”.

### 1. Configuration of Member for Semiconductor Manufacturing Equipment

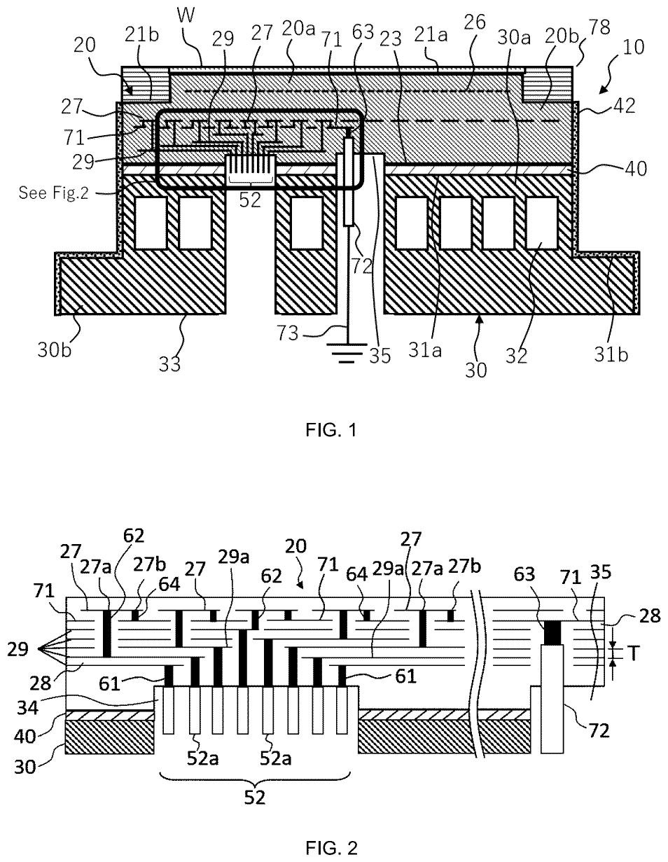

Referring to FIG. 1 and FIG. 2, a member 10 for a semiconductor manufacturing equipment according to an embodiment of the present invention can be used when performing processes such as CVD and etching on a wafer W using plasma, and can be fixed to a mounting plate (not shown) provided inside a semiconductor processing chamber. The member 10 for a semiconductor manufacturing equipment comprises a ceramic substrate 20 and a base plate 30 that is located on the side of the lower surface 23 of the ceramic substrate 20 and has a refrigerant passage 32 provided therein. The ceramic substrate 20 and the base plate 30 can be bonded together by, for example, a bonding layer 40.

### 1-1. Ceramic Substrate

According to an embodiment of the present invention, the ceramic substrate 20 comprises:
an upper surface 21a on which a wafer is to be placed,
a terminal dense portion 52 in which 10 or more terminals 52a are arranged within a single section,
a plurality of heater electrodes 27 which are zoned, and
a plurality of jumper electrode layers 29 that electrically connect the plurality of heater electrodes 27 to each terminal 52a of the terminal dense portion 52 and are stacked in a vertical direction via an insulator 28.

More specifically, the ceramic substrate 20 according to one embodiment of the present invention comprises a central portion 20a having a circular upper surface 21a in a planar view, and an outer peripheral portion 20b having an annular upper surface 21b in a planar view on the outer periphery of the central portion 20a. A wafer W can be placed on the upper surface 21a, and a focus ring 78 can be placed on the upper surface 21b. The ceramic substrate 20 is made of a ceramic material such as alumina or aluminum nitride. The upper surface 21b of the outer periphery 20b is one step lower than the upper surface 21a of the central portion 20a. The lower surface 23 of the central portion 20a and that of the outer peripheral portion 20b may be one the same plane. The ceramic substrate 20 may have the central portion 20a but no outer peripheral portion 20b, that is, may not have the upper surface 21b which is one step lower.

In the embodiment shown in FIG. 1, the upper surface of the focus ring 78 and that of the wafer W are flush with each other, but the upper surface of the focus ring 78 may be located higher than the wafer. In the embodiment shown in FIG. 1, the outer diameter of the focus ring 78 and the outer diameter of the outer peripheral portion 20b of the ceramic substrate 20 are the same, but the two outer diameters do not have to be the same.

The upper surface 21a on which the wafer W is to be placed may be provided with a plurality of small protrusions (not shown). Also, a seal band (not shown) may be formed along the outer edge of the upper surface 21a. In this case, the wafer W may be supported by the top surface of the seal band and the top surfaces of the small protrusions.

The central portion 20a of the ceramic substrate 20 may have a diameter of, for example, 190 to 450 mm and a thickness of 1 to 20 mm. In addition, the central portion 20a of the ceramic substrate 20 may incorporate an electrostatic adsorption electrode 26 on the side closer to the upper surface 21a. The electrostatic adsorption electrode 26 can be made of a material containing, for example, W, Mo, WC, MoC, or the like. The electrostatic adsorption electrode 26 may be, for example, a planar electrode. The ceramic substrate 20 may have one layer of the electrostatic adsorption electrode 26 therein, or two or more layers of the electrostatic adsorption electrode 26 therein with a gap therebetween.

The electrostatic adsorption electrode 26 is connected to an external DC power source via a power supply member (not shown). A low-pass filter may be disposed on the power supply member. The power supply member is electrically insulated from the bonding layer 40 and the base plate 30. When a DC voltage is applied to the electrostatic adsorption electrode 26, the wafer W is adsorbed and fixed to the upper surface 21a by electrostatic adsorption force, and when the application of the DC voltage is stopped, the wafer W is released from the adsorption and fixation to the upper surface 21a. The ceramic substrate 20 may incorporate an RF electrode for generating plasma in place of or in addition to the electrostatic adsorption electrode 26.

The ceramic substrate 20 also has a plurality of heater electrodes 27 which are zoned. The heater electrodes 27 are arranged, for example, such that a plurality of zones are formed in a planar direction parallel to the upper surface 21a of the ceramic substrate 20. The output of each of the zoned heater electrodes 27 can be controlled. As a result, the upper surface 21a of the ceramic substrate 20 is divided into a plurality of zones, and the temperature can be controlled for each zone, so that the performance of controlling the temperature distribution of the wafer can be improved.

The heater electrode 27 may be provided only in the central portion 20a of the ceramic substrate 20, but the heater electrode 27 may also be provided in the outer peripheral portion 20b of the ceramic substrate 20 (that is, under the focus ring 78).

In order to improve the performance of controlling the temperature distribution of the wafer, the ceramic substrate 20 preferably has 10 or more, more preferably 50 or more, and even more preferably 100 or more heater electrodes 27 in total. Each heater electrode 27 may be, for example, a linear electrode in a single stroke extending in a direction parallel to the upper surface 21a of the ceramic substrate 20. Each heater electrode 27 has a first connection portion 27 a which is a connection portion with a second via 62 and a second connection portion 27b which is a connection portion with a fourth via 64.

The heater electrode 27 can be made of, for example, a mixed material of metal and ceramics. Examples of metals include Ru, W, and Mo. One or a combination of two or more of these metals may be used, but those having a thermal expansion coefficient close to that of the ceramic material constituting the ceramic substrate 20 are preferable. As the ceramic, it is preferable to use the same material as that of the ceramic substrate 20 (for example, alumina, and aluminum nitride). By forming the heater electrode 27 from such a mixed material, the risk of cracks occurring between the heater electrode 27 and the ceramic substrate 20 due to the difference in thermal expansion between them can be reduced.

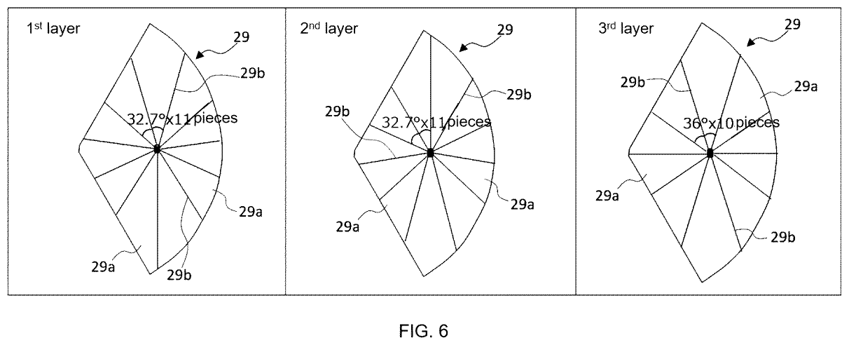

Each jumper electrode layer 29 is composed of a plurality of planar jumper electrodes 29a electrically separated via an insulator 29b (see FIG. 6). As the jumper electrode 29a is planar, there is an advantage that heat generation in the jumper electrode is suppressed compared to when the jumper electrode is linear. The fact that the jumper electrode 29a is planar means that the jumper electrode 29a extends in a plane direction parallel to the upper surface 21a of the ceramic substrate 20. Typically, the shape may be flat (for example, foil-like), but it may also have an uneven shape such as a mesh-like shape. The thickness of each planar jumper electrode 29a may be, for example, 10 to 100 μm, and typically 20 to 50 μm.

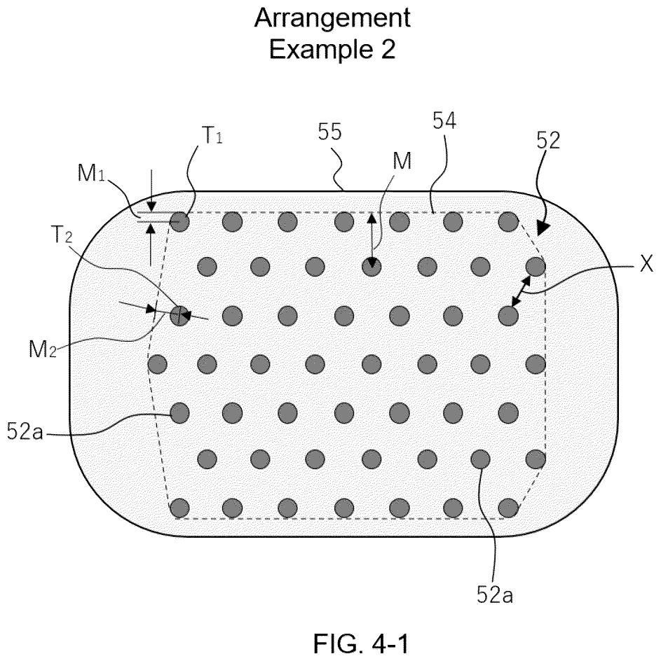

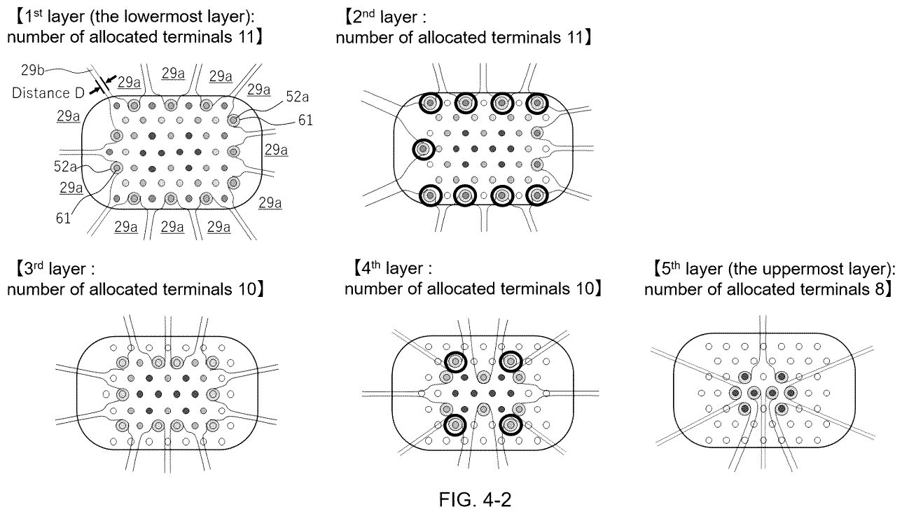

For any of the plurality of planar jumper electrodes 29a constituting at least one jumper electrode layer 29, preferably half or more of the jumper electrode layers 29, and more preferably all of the jumper electrode layers 29 among the plurality of jumper electrode layers 29 connected to the 10 or more terminals constituting the terminal dense portion in each single section, a distance D between adjacent planar jumper electrodes 29a in the same layer is preferably 0.1 mm or more, more preferably 0.2 mm or more, and even more preferably 0.3 mm or more (see FIG. 4-2). This reduces the risk of adjacent planar jumper electrodes 29a being electrically connected to each other, resulting in malfunction. On the other hand, from the viewpoint of reducing the risk of the jumper electrode width becoming narrower and generating more heat, the distance D is preferably 2 mm or less, more preferably 1.5 mm or less, and even more preferably 1 mm or less. Therefore, for any of the plurality of planar jumper electrodes 29a constituting at least one jumper electrode layer 29, preferably half or more of the jumper electrode layers 29, and more preferably all of the jumper electrode layers 29 among the plurality of jumper electrode layers 29 connected to the 10 or more terminals constituting the terminal dense portion in each single section, a distance D between adjacent planar jumper electrodes 29a in the same layer is preferably 0.1 to 2 mm, more preferably 0.2 to 1.5 mm, and even more preferably 0.3 to 1 mm.

The area of one planar jumper electrode 29a (excluding the opening) in a planar view is preferably 450 mm² or more, more preferably 700 mm² or more, and even more preferably 1400 mm² or more, for the reason of suppressing heat generation. In addition, the area of one planar jumper electrode 29a (excluding the opening) in a planar view is preferably 15,000 mm² or less, more preferably 7,000 mm² or less, and even more preferably 4,000 mm² or less, for the reason of simplifying electrode zoning. Therefore, the area of one planar jumper electrode 29a (excluding the opening) in a planar view is, for example, preferably 450 to 15,000 mm², more preferably 700 to 7,000 mm², and even more preferably 1,400 to 4,000 mm².

Each terminal 52a of the terminal dense portion 52 is electrically connected to a predetermined planar jumper electrode 29a through a first via 61 extending in the vertical direction. Each terminal 52a can be fixed to the ceramic substrate 20 by, for example, brazing. Further, each terminal 52a of the terminal dense portion 52 can be connected to a power supply member (not shown) that is connected to a heater power source. There are no particular limitations on the shape of each terminal 52a, but it may be, for example, a rigid rod extending in the vertical direction, or a flexible wire.

Each of the plurality of planar jumper electrodes 29a is electrically connected to a first connection portion 27a of a predetermined heater electrode 27 selected from the plurality of heater electrodes 27 via a second via 62 extending in the vertical direction. The second connection portion 27b of each of the plurality of heater electrodes 27 can be electrically connected to a common terminal 72 via a common jumper 71. The common terminal 72 can be connected to, for example, a ground (earth) wire. In addition, the common terminal 72 may be connected to a heater power supply. The common jumper 71 can be electrically connected to the common terminal 72 through a third via 63 extending in the vertical direction. In addition, the second connection portion 27b can be electrically connected to a common jumper 71 through a fourth via 64 extending in the vertical direction. In the illustrated embodiment, the common terminal 72 is inserted inside the ceramic substrate 20 and can be fixed by brazing. This configuration can increase the bonding strength of the common terminal 72. However, it is sufficient that the common terminal 72 is electrically connected to the common jumper 71, and it is not necessary for the common terminal 72 to be inserted inside the ceramic substrate 20. For example, the common terminal 72 may be fixed to the lower surface 23 of the ceramic substrate 20 or to the bottom surface of a recess 35 provided in the lower surface 23 by brazing.

The common jumper 71 can be formed at a different height from the jumper electrode layer 29 and the heater electrode 27 via the insulator 28. In the embodiment shown in FIG. 1, a common jumper 71 is formed between the jumper electrode layer 29 and the heater electrode 27. The position of the common jumper 71 is not limited to this, and it is also possible to provide it at a position of a layer above the heater electrode 27, for example.

One common jumper 71 can be electrically connected to all or some of the plurality of terminals of one or a plurality of terminal dense portions 52. In one embodiment, all of the plurality of terminals in one terminal dense portion 52 may be electrically connected to one common jumper 71. In another embodiment, among the plurality of terminals in one terminal dense portion 52, some terminals may be electrically connected to one common jumper 71, and the remaining terminals may be electrically connected to another common jumper 71. While there is an advantage in that the more common jumpers 71 there are, the more the current is dispersed and heat generation is suppressed, there is a disadvantage in that the number of common terminals 72 increases, resulting in increased costs and more complicated wiring. Therefore, the member 10 for a semiconductor manufacturing equipment preferably has 1 to 5 common jumpers 71 in total, and more preferably has 1 to 3 common jumpers 71 in total.

In a preferred embodiment, the common jumper 71 is planar, which has the advantage that heat generation is suppressed compared to when the common jumper 71 is linear. The fact that the common jumper 71 is planar means that the common jumper 71 extends in a plane direction parallel to the upper surface 21a of the ceramic substrate 20. Typically, the shape may be flat (for example, foil-like), but it may also have an uneven shape such as a mesh-like shape. The thickness of the common jumper 71 can be, for example, 10 to 100 μm, and typically 30 to 80 μm. Furthermore, the area of one common jumper 71 (excluding the opening) in a planar view is preferably 3,500 mm² or more, more preferably 7,000 mm² or more, and even more preferably 14,000 mm² or more, for the reason of suppressing heat generation. Furthermore, the area of one common jumper 71 (excluding the opening) in a planar view is preferably 70,000 mm² or less, and more preferably 40,000 mm² or less, for the reason of simplifying electrode zoning. Therefore, the area of one common jumper 71 (excluding the opening) in a plan view is, for example, preferably 3,500 to 70,000 mm², more preferably 7,000 to 40,000 mm², and even more preferably 14,000 to 40,000 mm².

One or more common terminals 72 may be provided for one terminal dense portion 52. However, from the viewpoint of suppressing heat generation caused by current concentration in the common terminal, it is preferable to provide more than one common terminal 72 for one terminal dense portion 52.

In the illustrated embodiment, the common terminal 72 is provided in a recess 35 provided in the lower surface 23 of the ceramic substrate 20. The recess 35 may be omitted. The common terminal 72 can be joined to the ceramic substrate 20 by, for example, brazing or soldering. There are no particular limitations on the common terminal 72, but it may be, for example, a rigid rod extending in the vertical direction, or a flexible cable.

The planar jumper electrode 29a and the common jumper 71 can be formed from, for example, a mixed material of ceramics and one or more selected from W, Mo, and Ru.

The first via 61, the second via 62, the third via 63, and the fourth via 64 can be formed from, for example, a mixed material of ceramics and one or more selected from W, Mo, and Ru.

The terminal 52a and the common terminal 72 can be made of a material such as Mo or Kovar (Fe—Ni—Co alloy).

The third via 63 is prone to generate heat because current supplied through each terminal 52a is concentrated in the third via 63.

Therefore, in order to suppress excessive heat generation in the third via 63, it is preferable that the diameter of the third via 63 be larger than the diameter of the first via. The ratio of the diameter X₃ of the third via to the diameter X₁ of the first via may be set appropriately taking into consideration the current flowing through the third via, and may be, for example, 2≤X₃/X₁≤25, and typically, 4≤X₃/X₁≤10.

The diameter X₁ of the first via can be, for example, 50 to 1000 μm, and typically 100 to 400 μm.

The diameter X₂ of the second via can be, for example, 50 to 1000 μm, and typically 100 to 400 μm.

The diameter X₃ of the third via can be, for example, 300 to 5000 μm, and typically 500 to 2000 μm.

The diameter X₄ of the fourth via can be, for example, 50 to 1000 μm, and typically 100 to 400 μm.

As used herein, the diameters of the first, second, third and fourth vias refer to the equivalent circle diameters in a cross section perpendicular to the extension direction of each via.

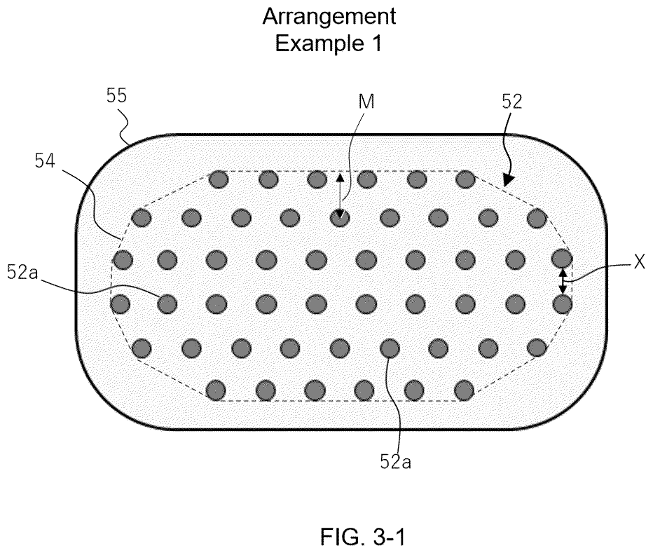

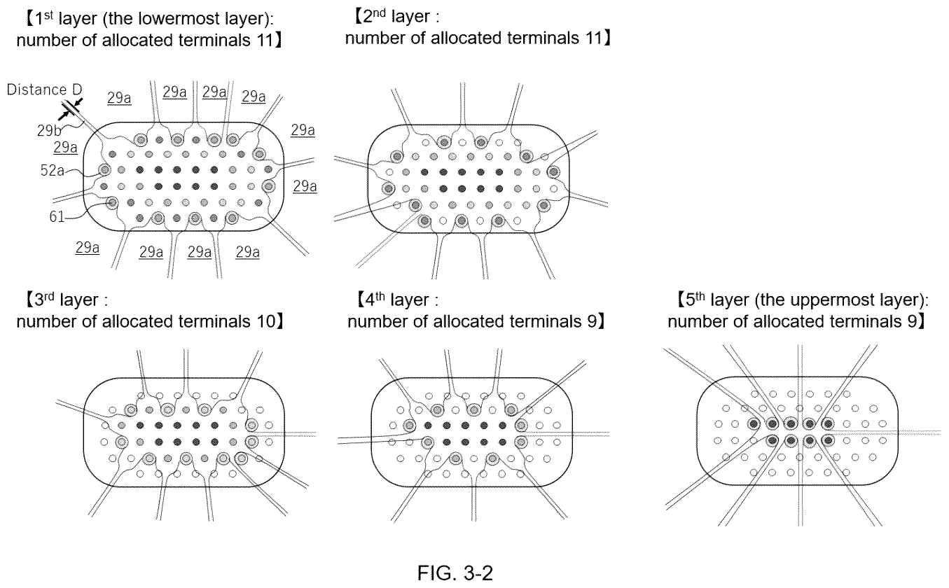

The terminal dense portion 52 is a portion in which 10 or more terminals 52a are arranged within a single section 55 (see FIG. 3-1). In the embodiment shown in FIG. 1, only one terminal dense portion 52 is shown. Depending on the wiring that supplies power to the terminals, the ceramic substrate 20 may be provided with a plurality of terminal dense portions 52, that is, a plurality of single sections 55. There is no particular limit to the number of terminals 52a arranged in the terminal dense portion 52 within a single section 55, but it may be, for example, 10 to 100, and typically 20 to 70. In the embodiment shown in FIG. 1, the terminal dense portion 52 is provided in a recess 34 provided in the lower surface 23 of the ceramic substrate 20, and a single section 55 is partitioned by the recess 34. The recess 34 may not be provided. In addition, from the viewpoints of saving space and ensuring insulation between the terminals, the number density of the terminals 52a arranged in the terminal dense portion 52 is preferably 10 to 100 pieces/cm², more preferably 30 to 90 pieces/cm², and even more preferably 50 to 80 pieces/cm². The number density of the terminals 52a arranged in the terminal dense portion 52 is obtained by dividing the number of terminals arranged in the terminal dense portion 52 by the area of the region surrounded by the outer periphery 54 of the terminal dense portion 52. The outer periphery 54 will be defined later.

From the viewpoint of saving space and ensuring insulation among the terminals, for each of the 10 or more terminals 52a arranged in a single section 55, it is preferable that the shortest distance X (insulated distance) from the nearest terminal 52a among the adjacent terminals 52a is 0.3 to 2 mm, more preferably 0.5 to 1.5 mm, and even more preferably 0.7 to 1.3 mm (see FIG. 3-1 and FIG. 4-1).

The plurality of jumper electrode layers 29 electrically connect the plurality of heater electrodes 27 to each terminal 52a of the terminal dense portion 52, and are stacked in the vertical direction via the insulator 28. The distance between vertically adjacent jumper electrode layers 29 (equal to the thickness T of the insulator 28 between the layers) is preferably 0.02 to 1 mm, more preferably 0.02 to 0.5 mm, and even more preferably 0.02 to 0.2 mm, in order to strike a balance between ensuring insulation between the vertically adjacent jumper electrode layers 29 and reducing the manufacturing cost by thinning the ceramic substrate 20.

Since an increase in the number of jumper electrode layers 29 increases the number of laminations, which increases the manufacturing cost, it is desirable to keep the number of jumper electrode layers 29 as small as possible. In order to reduce the number of jumper electrode layers 29, it is preferable that each jumper electrode layer 29 have a plurality of planar jumper electrodes 29a.

Thus, in one embodiment, each jumper electrode layer 29 may be comprised of a plurality of planar jumper electrodes 29a electrically separated by insulators 29b (see FIG. 6). While a larger number of jumper electrodes 29a in the same jumper electrode layer 29 helps to reduce the number of jumper electrode layers 29, it is not desirable to have an excessively large number of jumper electrodes 29a since a narrower width of each jumper electrode 29a will result in greater heat generation. Therefore, it is desirable that at least one jumper electrode layer 29, preferably half or more jumper electrode layers 29, and more preferably all of the jumper electrode layers 29 among the plurality of jumper electrode layers 29 electrically connected to the 10 or more terminals 52a constituting the terminal dense portion 52 in each single section 55 be composed of 5 to 15 planar jumper electrodes 29a, and more preferably composed of 8 to 12 planar jumper electrodes 29a.

As the insulator 29b for electrically isolating the plurality of planar jumper electrodes 29a, for example, the ceramics (alumina and/or aluminum nitride, or the like) constituting the ceramic substrate 20 can be used. Further, without being limited thereto, a type of ceramic different from the ceramic constituting the ceramic substrate 20 may be used as the insulator 29b.

Each terminal 52a of the terminal dense portion 52 is electrically connected to a predetermined planar jumper electrode 29a through a first via 61 extending in the vertical direction. One terminal 52a may be electrically connected to a plurality of planar jumper electrodes 29a, or a plurality of terminals 52a may be electrically connected to one planar jumper electrode 29a. In a preferred embodiment, each of the terminals 52a is connected to one predetermined planar jumper electrode 29a.

In order to reduce the number of jumper electrode layers 29, it is necessary to electrically connect the numerous terminals 52a arranged in the terminal dense portion 52 to each jumper electrode 29a through the first vias 61 with high spatial efficiency. Specifically, it is desirable to connect the first via 61 connected to the terminal 52a on the outer periphery of the terminal dense portion 52 to the jumper electrode layer 29 on the lower layer side, and to connect the first via 61 connected to the terminal 52a on the inner periphery to the jumper electrode layer 29 on the upper layer side. Therefore, in one embodiment, in at least one terminal dense portion 52, each of 70% or more of all the terminals 52a, preferably each of 80% or more of all the terminals 52a, and more preferably each of all the terminals 52a arranged in the terminal dense portion 52 is electrically connected to a predetermined planar jumper electrode 29a through the first via 61 extending in the vertical direction, on a condition that it is not electrically connected to a planar jumper electrode 29a located in a layer above any other planar jumper electrodes 29a to which other terminals that have a longer distance from the outer periphery 54 of the terminal dense portion 52 than itself are electrically connected. That is, when a terminal A, which is closer to the outer periphery 54 of the terminal dense portion 52, is compared with a terminal B, which is more distant from the outer periphery 54 of the terminal dense portion 52 than the terminal A, it is preferable that the planar jumper electrode 29a to which the terminal A is connected belongs to the same jumper electrode layer 29 as the planar jumper electrode 29a to which the terminal B is connected, or alternatively, it is preferable that the planar jumper electrode 29a to which the terminal A is connected belongs to a jumper electrode layer 29 located in a lower layer than the planar jumper electrode 29a to which the terminal B is connected.

Of all the terminals 52a arranged in the terminal dense portion 52, some of the terminals 52a do not need to satisfy the above condition. Therefore, in at least one of the terminal dense portions 52, at least one terminal 52a (T₁) may be electrically connected to a planar jumper electrode 29a located in a layer above a planar jumper electrode 29a to which at least one other terminal 52a (T₂), which has a longer distance from the outer periphery 54 of the terminal dense portion 52 than the at least one terminal T₁, is electrically connected. However, assuming the distance between the at least one terminal 52a (T₁) and the outer periphery 54 is M₁ (mm), and the distance between the at least one other terminal 52a (T₂) and the outer periphery 54 is M₂ (mm), it is preferable that a formula 1: M₁<M₂≤M₁+2 is satisfied for all of the terminals 52a (T₁).

When the ceramic substrate 20 has a plurality of terminal dense portions 52, it is preferable that a half or more than half of the terminal dense portions 52 satisfy the above condition, and it is more preferable that all of the terminal dense portions 52 satisfy the above condition. There is no particular limit to the number of the terminal dense portions 52, and it may be set appropriately depending on the area of the upper surface 21a, which is the wafer placement surface of the ceramic substrate 20, the number of heater electrodes 27, the number of jumper electrode layers 29, and the like. Exemplarily, it may be 1 to 10, typically 1 to 5.

FIGS. 3-1 and 4-1 show an arrangement example 1 and an arrangement example 2 when the terminal dense portion 52 in a single section 55 is observed from the lower surface 23 side of the ceramic substrate 20. The outer periphery 54 of the terminal dense portion 52 is defined as a convex hull (the smallest convex set) that contains all the terminals 52a in a single section 55 to which the terminal dense portion 52 belongs. In addition, the distance between each terminal 52a and the outer periphery 54 refers to the shortest distance M from the center of gravity of the terminal 52a to the outer periphery 54 when the terminal 52a is observed in a direction perpendicular to the surface to which the terminal 52a is connected.

FIG. 3-2 shows an example diagram explaining the allocation when each terminal 52a of the terminal dense portion 52 in the arrangement example 1 is electrically connected to the planar jumper electrode 29a of the jumper electrode layer 29 consisting of five layers via the first via 61. In other words, FIG. 3-2 illustrates, by way of example, jumper electrode layers 29 to which each terminal 52a of the terminal dense portion 52 is electrically connected, from the lowermost layer (1^{st} layer) to the uppermost layer (5^{th} layer). In the 1^{st} layer, 11 terminals 52a located on the outermost periphery are allocated. In the 2^{nd} layer, 9 terminals 52a located on the outermost periphery and 2 terminals 52a located one step inward from the outermost periphery are allocated. In the 3^{rd} layer, 10 terminals 52a located one step inward from the outermost periphery are allocated. In the 4^{th} layer, 6 terminals 52a located one step inward from the outermost periphery and 3 terminals 52a located two steps inward from the outermost periphery are allocated. In the 5^{th} layer, 9 terminals 52a located two steps inward from the outermost periphery are allocated.

In the arrangement example 1, for all the terminals 52a, the condition is satisfied that the terminal 52a is not electrically connected to a planar jumper electrode located in a layer above any other planar jumper electrode to which other terminals that have a longer distance from the outer periphery 54 of the terminal dense portion 52 than itself are electrically connected.

FIG. 4-2 shows an example diagram explaining the allocation when each terminal 52a of the terminal dense portion 52 in the arrangement example 2 is electrically connected to the planar jumper electrode 29a of the jumper electrode layer 29 consisting of five layers via the first via 61. In other words, FIG. 4-2 illustrates, by way of example, jumper electrode layers 29 to which each terminal 52a of the terminal dense portion 52 is electrically connected, from the lowermost layer (1^{st} layer) to the uppermost layer (5^{th} layer). In the 1^{st} layer, 11 terminals 52a are allocated. In the 2^{nd} layer, 11 terminals 52a are allocated. In the 3^{rd} layer, 10 terminals 52a are allocated. In the 4^{th} layer, 10 terminals 52a are allocated. In the 5^{th} layer, 8 terminals 52a are allocated.

In the arrangement example 2, a total of 50 terminals 52 a are arranged in the terminal dense portion 52. In FIG. 4-2, 13 terminals 52a (9 on the 2^{nd} layer and 4 on the 4^{th} layer) surrounded by thick circles do not satisfy the condition that the terminal 52a is not electrically connected to a planar jumper electrode located in a layer above any other planar jumper electrode to which other terminals 52a that have a longer distance from the outer periphery 54 of the terminal dense portion 52 than itself are electrically connected. The remaining 37 terminals 52a (74%) satisfy this condition.

In a preferred embodiment, assuming the total number of the plurality of jumper electrode layers 29 electrically connected to the 10 or more terminals 52a constituting the terminal dense portion 52 in each single section 55 is A, the number of planar jumper electrodes 29a constituting the N^{th} jumper electrode layer (N is a natural number from 1 to A) from the lowermost layer is equal to or less than the number of planar jumper electrodes 29a constituting the (N−1)^{th} jumper electrode layer 29 from the lowermost layer, and the number of the planar jumper electrodes 29a constituting the uppermost jumper electrode layer 29 is less than the number of the planar jumper electrodes 29a constituting the lowermost jumper electrode layer 29. A wider distance between electrodes of the jumper electrodes 29a is preferable from the viewpoint of insulation between the electrodes, and a wider width of the electrodes is preferable from the viewpoint of suppressing heat generation. Therefore, by adopting this configuration in which jumper electrodes connected to terminals on the outer periphery, where it is easier to ensure the distance between electrodes and the width of electrodes, are arranged on the lower layer side, it is possible to obtain the advantage of being able to arrange jumper electrodes efficiently using a minimum number of layers.

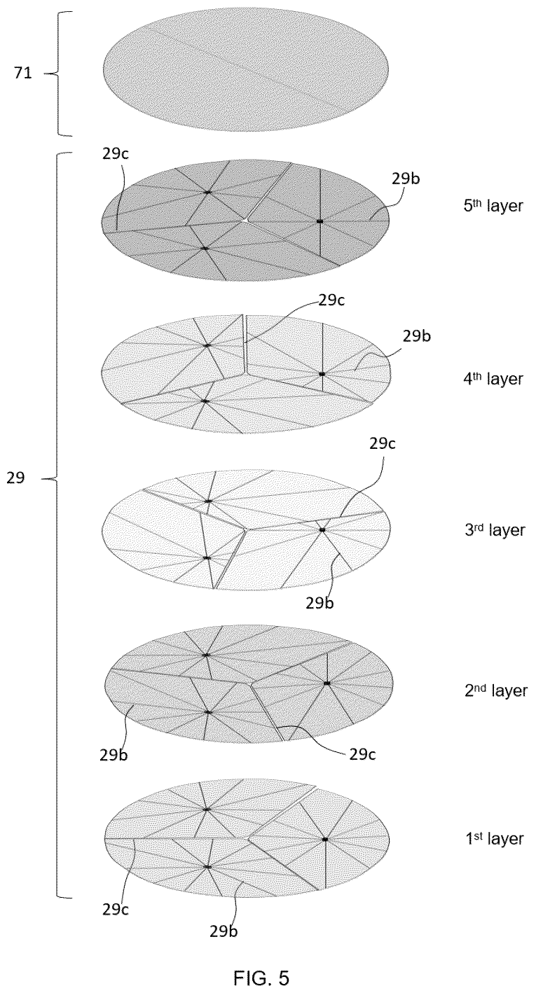

FIG. 5 shows schematic examples of the shapes of the plurality of planar jumper electrodes 29a constituting each of the jumper electrode layers 29 from the 1^{st} to the 5^{th} layers and an example of the shape of a common jumper, when the upper surface 21a, which is the wafer placement surface of the ceramic substrate 20, is circular, the number of terminal dense portions 52 is three, and the number of jumper electrode layers 29 is five. In the embodiment shown in FIG. 5, the planar shape of one jumper electrode layer 29 electrically connected to the plurality of terminals 52a in one terminal dense area 52 is substantially a sector with the center of the circle formed by the upper surface 21a as the reference for the central angle. In the embodiment shown in FIG. 5, three jumper electrode layers 29 are arranged at the same height in each of the 1^{st} to 5^{th} layers. The three jumper electrode layers 29 are electrically connected to the corresponding terminal dense portions 52. The three jumper electrode layers 29 at the same height (same layer number) are arranged so as to correspond as a whole to the planar shape (circular in FIG. 5) of the upper surface 21a which is the wafer placement surface.

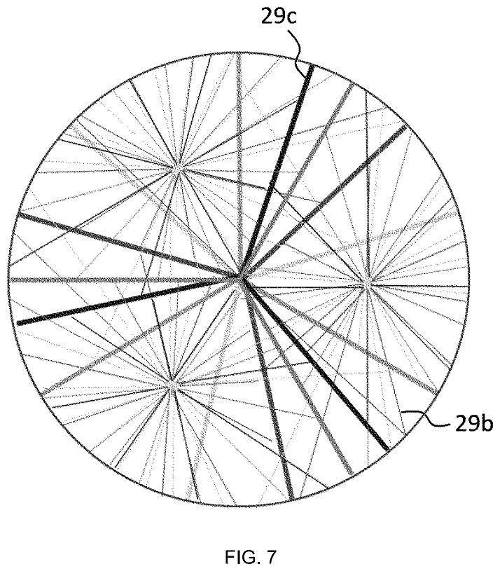

In the embodiment shown in FIG. 5, the three jumper electrode layers 29 at the same height (the same layer number) all have a substantially sector shape with substantially the same central angle (specifically, 120°), and are electrically isolated from each other by linear insulators 29c (for example, ceramics) extending along the radius. It is preferable that the linear insulators 29c electrically isolating the adjacent jumper electrode layers 29 from each other do not linearly overlap in the vertical direction with any linear insulators 29c in different jumper electrode layers 29. FIG. 7 shows a schematic sight-through view of a plurality of planar jumper electrodes constituting the five jumper electrode layers shown in FIG. 5 as viewed virtually from above. This can reduce the risk of cracks occurring in the ceramic substrate 20. The line width of the linear insulator 29c (equal to the distance between adjacent jumper electrode layers 29) is not limited to, but may be, for example, 0.3 to 2 mm, and typically 0.3 to 1 mm.

FIG. 6 shows a schematic plan view of each of the 1^{st} to 3^{rd} jumper electrode layers 29 as an example. It is preferable that each of the plurality of planar jumper electrodes 29a constituting at least one jumper electrode layer 29, preferably half or more of the jumper electrode layers 29, and more preferably all of the jumper electrode layers among the plurality of jumper electrode layers 29 electrically connected to the 10 or more terminals 52a constituting the terminal dense portion 52 in each single section 55 have a planar shape having two adjacent line segments at the same angle with the position of the first via 61 as a vertex. Current tends to concentrate and generate heat near the first via 61 extending in the vertical direction from the terminal dense portion 52. Therefore, by spreading the planar jumper electrodes 29a at equal intervals, it is possible to obtain an advantage that the heat can be easily dispersed.

Referring to FIG. 6, in the 1^{st} and 2^{nd} jumper electrode layers 29, each of the 11 pieces of jumper electrodes 29a has a planar shape having two line segments as a component adjacent at an angle of 32.7° (=360°/11). In the 3^{rd} jumper electrode layer 29, each of the 10 pieces of jumper electrodes 29a has a planar shape having two line segments as a component adjacent at an angle of 36° (=360°/10).

In each of the multiple jumper electrode layers 29 connected to the 10 or more terminals 52a constituting the terminal dense portion 52 in each single section 55, adjacent planar jumper electrodes 29a can be electrically isolated from each other by the linear insulators 29b (for example, ceramics). The linear insulator 29b may be formed, for example, with a straight line, a curved line, or a combination of both. In this case, it is preferable that the linear insulators 29b do not linearly overlap with any linear insulators 29b in different jumper electrode layers 29 in the vertical direction. FIG. 7 shows a schematic sight-through view of a plurality of planar jumper electrodes constituting the 5 jumper electrode layers shown in FIG. 5 as viewed virtually from above. This reduces the risk of cracks occurring in the ceramic substrate. The line width of the linear insulator 29b (equal to the distance between adjacent jumper electrodes 29a) is not limited, but may be, for example, 0.3 to 2 mm, and typically 0.5 to 1 mm.

From the viewpoint of reducing manufacturing costs, the total layer number A of the jumper electrode layers 29 is preferably 20 or less, more preferably 10 or less, and even more preferably 5 or less. On the other hand, from the viewpoint of increasing the number of heater electrodes to increase the number of zones and thereby improving the performance of controlling the temperature distribution of the wafer, the total layer number A of jumper electrode layers 29 is preferably 2 or more, more preferably 3 or more, and even more preferably 4 or more. Therefore, the total layer number A of the jumper electrode layers 29 is, for example, preferably 2 to 20, more preferably 3 to 10, and even more preferably 4 to 5.

### 1-2. Base Plate

The base plate 30 may be, for example, circular plate-shaped. In one embodiment, the base plate 30 comprises a central portion 30a having a circular upper surface 31a in a plan view, and a flange portion 30b having an annular upper surface 31b in a plan view on the outer periphery of the central portion 30a. The thickness of the central portion 30a may be, for example, 5 to 30 mm. The flange portion 30b can be used to clamp or bolt the member 10 for a semiconductor manufacturing equipment to a mounting plate disposed on the side of the lower surface 33. Also, a ring heater (not shown) can be placed on the flange portion 30b. In this case, the ring heater can be bolted to the mounting plate.

The base plate 30 can be made of, for example, a metal material or a composite material of metal and ceramics. Examples of metal materials include Al, Ti, Mo, and alloys thereof. Examples of composite materials of metal and ceramics include metal matrix composites (MMCs) and ceramic matrix composites (CMCs). Specific examples of such composite materials include materials containing Si, SiC, and Ti (also called SiSiCTi), materials in which a porous SiC body is impregnated with Al and/or Si, and composite materials of Al₂O₃ and TiC. A material in which a porous SiC body is impregnated with Al is called AlSiC, and a material in which a porous SiC body is impregnated with Si is called SiSiC. It is preferable to select a material for the base plate 30 that has a thermal expansion coefficient close to that of the ceramics that constitutes the ceramic substrate 20. For example, when the ceramic substrate 20 is made of alumina, the base plate 30 is preferably made of SiSiCTi or AlSiC, which have a thermal expansion coefficient close to that of alumina.

The base plate 30 can be used as an RF electrode by connecting it to an RF power source via a power supply terminal (not shown). A high pass filter (HPF) can be disposed between the base plate 30 and the RF power source.

Inside the base plate 30, a refrigerant passage 32 through which refrigerant circulates may be formed. The refrigerant flowing through the refrigerant passage 32 is preferably liquid and preferably electrically insulating. An example of the electrically insulating liquid includes fluorine-based inert liquid. The refrigerant passage 32 can be formed, for example, in a single stroke across the entire base plate 30 from one end (inlet) to the other end (outlet) in a plan view. A supply port and a recovery port of an external refrigerant device (not shown) are connected to one end and the other end of the refrigerant passage 32, respectively. The refrigerant supplied from the supply port of the external refrigerant device to one end of the refrigerant passage 32 passes through the refrigerant passage 32 and then returns from the other end of the refrigerant passage 32 to a recovery port of the external refrigerant device, and after the temperature has been adjusted, the refrigerant is again supplied to the one end of the refrigerant passage 32 from the supply port.

### 1-3. Bonding Layer

The bonding layer 40 bonds the lower surface 23 of the ceramic substrate 20 to the upper surface 31a of the base plate 30. The bonding layer 40 may be composed of a metal layer made of, for example, solder or a metal brazing material. The bonding layer 40 is formed, for example, by TCB (Thermal Compression Bonding). TCB refers to a known method in which a metal bonding material is sandwiched between two members to be bonded, and the two members are pressure-bonded while being heated to a temperature equal to or lower than the solidus temperature of the metal bonding material. The bonding layer 40 is not limited to a metal layer. For example, a resin bonding layer may be used instead of the metal layer. The resin bonding layer may be made of, for example, a silicone resin-based adhesive, an epoxy resin-based adhesive, an acrylic resin-based adhesive, or a urethane resin-based adhesive.

The bonding layer 40 and the base plate 30 may have a through hole at a location corresponding to the terminal dense portion 52 in order to facilitate connection of power supply member to the respective terminals 52a of the terminal dense portion 52. In addition, the bonding layer 40 and the base plate 30 may have a through hole at a location corresponding to the common terminal 72 such that the common terminal 72 can be easily connected to the ground wire 73.

### 1-4. Others

The side surface of the outer peripheral portion 20b of the ceramic substrate 20, the outer periphery of the bonding layer 40, the side surface of the base plate 30, and the upper surface 31b of the flange portion 30b can be covered with an insulating film 42. An example of the insulating film 42 includes a thermally sprayed film of alumina, yttria, or the like.

In the above-described embodiment, the member 10 for a semiconductor manufacturing equipment may have a plurality of holes that pass through the member 10 for a semiconductor manufacturing equipment in the vertical direction. Such holes include a plurality of gas holes opening in the upper surface 21a and a lift pin hole for inserting a lift pin that moves the wafer

W up and down relative to the upper surface 21a. A plurality of gas holes can be provided at appropriate positions in a planar view of the upper surface 21a. A thermally conductive gas such as He gas is supplied to the gas holes. Normally, the gas holes can be provided so as to have an opening on the upper surface 21a on which the above-mentioned seal band or small protrusions are provided, but at positions where the seal band or small protrusions are not provided. When the thermally conductive gas is supplied to the gas holes, the thermally conductive gas fills the space on the rear side of the wafer W placed on the upper surface 21a. Gas passage may be embedded in the gas holes. A plurality of lift pin holes may be provided at equal intervals along a concentric circle on the upper surface 21a in a planar view of the upper surface 21a.

### 2. Method of Using a Member for Semiconductor Manufacturing Equipment

Next, an example of how to use the member 10 for a semiconductor manufacturing equipment will be described. The common terminal 72 of the member 10 for a semiconductor manufacturing equipment is connected to earth via the earth wire 73. Further, each terminal 52a of the terminal dense portion 52 is connected to a heater power supply via a power supply member (not shown). In this state, when a voltage is applied from the heater power supply, a current flows in the order of each terminal 52a in the terminal dense portion 52→the first via 61→the jumper electrode layer 29→the second via 62→each heater electrode 27→the fourth via 64→the common jumper 71→the third via 63→the common terminal 72, so that each heater electrode 27 generates heat. By changing the voltage applied to each terminal 52a, it is possible to change the amount of heat generated by the zoned multiple heater electrodes 27. This makes it possible to realize a desired heat distribution on the ceramic substrate 20, and therefore, for example, it is possible to control the temperature distribution of the wafer W fixed by adsorption to the upper surface 21a of the ceramic substrate 20.

A method for adsorbing and fixing a wafer W will be described below. First, the wafer W is placed on the upper surface 21a of the ceramic substrate 20 with the member 10 for a semiconductor manufacturing equipment placed in a chamber (not shown). Then, the pressure inside the chamber is reduced using a vacuum pump to adjust it to a predetermined degree of vacuum, and a voltage is applied to the electrostatic adsorption electrode 26 to generate an electrostatic adsorption force, thereby adsorbing and fixing the wafer W to the upper surface 21a of the ceramic substrate 20. A method for processing the wafer W will now be described. The

inside of the chamber is set to a reaction gas atmosphere at a predetermined pressure (for example, several tens to several hundreds of Pa). The zoned multiple heater electrodes 27 are controlled such that the temperature distribution of the wafer W fixed by adsorption to the upper surface 21a of the ceramic substrate 20 becomes a desired state. Plasma is then generated by applying a high-frequency voltage such as an RF voltage between an upper electrode (not shown) provided on the ceiling of the chamber and the base plate 30 of the member 10 for a semiconductor manufacturing equipment. The surface of the wafer W is processed by the generated plasma.

### 3. Method for Manufacturing a Member for Semiconductor Manufacturing Equipment

Next, a method for manufacturing the member 10 for a semiconductor manufacturing equipment will be exemplarily described.

First, a method for producing the ceramic substrate 20 will be described. A plurality of circular plate-shaped green sheets that are the precursor of the ceramic substrate 20 are produced. The green sheets can be produced by, for example, a tape forming process. Grooves are formed in the lower surface of the first green sheet from the bottom layer at positions where the recesses 34 and 35 are to be provided. Further, a through hole is formed in the green sheet at a position corresponding to the first via 61, and the through hole is filled with a conductive paste to form a paste-filled portion. Furthermore, if necessary, a through hole is also formed at a position where the common terminal 72 is to be inserted. Next, a conductive paste is printed on the upper surface of the green sheet so as to obtain the same pattern as the 1^{st} jumper electrode layer 29, thereby forming a jumper precursor for the 1^{st} layer.

For the second green sheet from the lowermost layer onwards (N^{th} layer), through holes are formed at positions corresponding to the first via 61, the second via 62, the third via 63, and the fourth via 64 as necessary, and the through holes are filled with conductive paste to form paste-filled portions. Furthermore, if necessary, a through hole is formed at the position where the common terminal 72 is to be inserted. Next, a conductive paste is printed on the upper surface of the green sheet in the same pattern as the jumper electrode layer 29, the common jumper 71 or the heater electrode 27 required in the order from the lowermost layer, thereby forming a jumper precursor. The uppermost green sheet can be used without any processing.

The green sheets, which have been subjected to the predetermined processing, are stacked in order from the lowermost layer to the uppermost layer to form a laminate. This laminate is fired to obtain the ceramic substrate 20. The electrostatic adsorption electrode 26 and vias (not shown) connected to the electrostatic adsorption electrode 26 can be formed inside the ceramic substrate 20 by a standard method.

A base plate 30 and a metal bonding material are prepared in addition to the ceramic substrate 20. The base plate 30 has a refrigerant passage 32. Additionally, the base plate 30 and the metal bonding material may have through holes for accessing the recesses 34 and 35 of the ceramic substrate 20. The base plate 30 having the refrigerant passage 32 can be manufactured, for example, by joining multiple aluminum or MMC plate members in which grooves or holes corresponding to the refrigerant passage 32 have been formed by machining using a method such as electron beam, welding, diffusion bonding, or TCB. The through holes can be formed by machining.

Next, a resin or metal bonding material is sandwiched between the lower surface 23 of the ceramic substrate 20 and the upper surface 31a of the base plate 30 to form a laminate. Then, the laminate is pressurized and bonded at a temperature no higher than the solidus temperature of the metal bonding material 90 (for example, the temperature 20° C. lower than the solidus temperature or more and no higher than the solidus temperature), and then returned to room temperature (TCB). As a result, the metal bonding material becomes the bonding layer 40, and a bonded body is obtained in which the ceramic substrate 20 and the base plate 30 are bonded together by the bonding layer 40. It is preferable to use a metal bonding material having a thickness of about 100 μm (for example, 80 to 240 μm).

Thereafter, the plurality of terminals 52a constituting the terminal dense portion 52 are connected to the corresponding first vias 61 by a method such as brazing. Further, the common terminal 72 is connected to the third via 63 by a method such as brazing. Thereafter, the member 10 for a semiconductor manufacturing equipment is completed by appropriately going through processes such as adjusting the overall shape.

### DESCRIPTION OF REFERENCE NUMERALS

10: Member for semiconductor manufacturing equipment
20: Ceramic substrate
20a: Center portion
20b: Outer peripheral portion
21a: Upper surface
21b: Upper surface
23: Lower surface
26: Electrostatic adsorption electrode
27: Heater electrode
27a: First connection portion
27b: Second connection portion
28: Insulator
29: Jumper electrode layer
29a: (Planar) jumper electrode
29b: Insulator
29c: Insulator
30: Base plate
30a: Central portion
30b: Flange portion
31a: Upper surface
31b: Upper surface
32: Refrigerant passage
33: Lower surface
34: Recess
35: Recess
40: Bonding layer
42: Insulating film
52: Terminal dense portion
52a: Terminal
54: Outer periphery
55: Single section
61: First via
62: Second via
63: Third via
64: Fourth via
71: Common jumper
72: Common terminal
73: Earth wire
78: Focus ring
W: Wafer

1. A member for a semiconductor manufacturing equipment comprising a ceramic substrate, the ceramic substrate comprising:
an upper surface on which a wafer is to be placed,
a terminal dense portion in which 10 or more terminals are arranged within a single section,
a plurality of heater electrodes which are zoned, and
a plurality of jumper electrode layers that electrically connect the plurality of heater electrodes to each terminal of the terminal dense portion and are stacked in a vertical direction via an insulator;
wherein each of the jumper electrode layers is composed of a plurality of planar jumper electrodes that are electrically isolated by an insulator,
wherein in at least one of the terminal dense portion, each of 70% or more of all the terminals arranged in the terminal dense portion is electrically connected to a predetermined planar jumper electrode through a first via extending in the vertical direction, on a condition that it is not electrically connected to a planar jumper electrode located in a layer above any other planar jumper electrode to which other terminals that have a longer distance from an outer periphery of the terminal dense portion than itself are electrically connected, and
wherein each of the plurality of planar jumper electrodes is electrically connected to a first connection portion of a predetermined heater electrode selected from the plurality of heater electrodes through a second via extending in the vertical direction.

2. A member for a semiconductor manufacturing equipment according to claim 1, wherein in at least one of the terminal dense portion, at least one terminal T₁ is electrically connected to a planar jumper electrode located in a layer above a planar jumper electrode to which at least one other terminal T₂, which has a longer distance from the outer periphery of the terminal dense portion than the at least one terminal T₁, is electrically connected; and wherein assuming a distance between the at least one terminal T₁ and the outer periphery is M₁ (mm), and a distance between the at least one other terminal T₂ and the outer periphery is M₂ (mm), a formula 1: M₁<M₂≤M₁+2 is satisfied for all of the at least one terminal T₁.

3. A member for a semiconductor manufacturing equipment according to claim 1, wherein in at least one of the terminal dense portion, each of all the terminals arranged in the terminal dense portion is electrically connected to the predetermined planar jumper electrode through the first via extending in the vertical direction, on the condition that it is not electrically connected to the planar jumper electrode located in the layer above any other planar jumper electrode to which other terminals that have a longer distance from the outer periphery of the terminal dense portion than itself are electrically connected.

4. A member for a semiconductor manufacturing equipment according to claim 1, wherein at least one jumper electrode layer among the plurality of jumper electrode layers electrically connected to the 10 or more terminals constituting the terminal dense portion in each single section is composed of 8 to 12 planar jumper electrodes.

5. A member for a semiconductor manufacturing equipment according to claim 1, wherein assuming a total number of the plurality of jumper electrode layers electrically connected to the 10 or more terminals constituting the terminal dense portion in each single section is A, a number of planar jumper electrodes constituting a N^{th} jumper electrode layer (N is a natural number from 1 to A) from a lowermost layer is equal to or less than a number of planar jumper electrodes constituting the (N−1)^{th} jumper electrode layer from the lowermost layer, and a number of the planar jumper electrodes constituting the uppermost jumper electrode layer is less than a number of the planar jumper electrodes constituting the lowermost jumper electrode layer.

6. A member for a semiconductor manufacturing equipment according to claim 1, wherein each of the plurality of planar jumper electrodes constituting at least one jumper electrode layer among the plurality of jumper electrode layers electrically connected to the 10 or more terminals constituting the terminal dense portion in each single section has a planar shape having two adjacent line segments at the same angle with a position of the first via as a vertex.

7. A member for a semiconductor manufacturing equipment according to claim 1, wherein each of the plurality of the heater electrodes has a second connection portion, and the second connection portion is connected to a common terminal for grounding via a common jumper.

8. A member for a semiconductor manufacturing equipment according to claim 7, wherein the common jumper is electrically connected to the common terminal through a third via extending in the vertical direction, and a diameter of the third via is larger than a diameter of the first via.

9. A member for a semiconductor manufacturing equipment according to claim 1, wherein in each of the plurality of jumper electrode layers connected to the 10 or more terminals constituting the terminal dense portion in each single section, adjacent planar jumper electrodes are electrically isolated from each other by a linear insulator, and the linear insulator does not linearly overlap any other linear insulator in a different jumper electrode layer in the vertical direction.

10. A member for a semiconductor manufacturing equipment according to claim 1, wherein for any of the plurality of planar jumper electrodes constituting at least one jumper electrode layer among the plurality of jumper electrode layers connected to the 10 or more terminals constituting the terminal dense portion in each single section, a distance between adjacent planar jumper electrodes in the same layer is 0.3 mm or more.
